(19) United States
(12) Patent Application Publication
(10) Pub. No.: US 2026/0255848 A1
(43) Pub. Date: Aug. 27, 2026

(54) DISPLAY DEVICE AND DISPLAY PANEL

(71) Applicant: LG Display Co., Ltd., Seoul (KR)

(72) Inventors: Yein HONG, Paju-si (KR); JunYoung KWON, Paju-si (KR)

(73) Assignee: LG Display Co., Ltd., Seoul (KR)

(21) Appl. No.: 19/387,046

(22) Filed: Nov. 12, 2025

(30) Foreign Application Priority Data
Feb. 27, 2025 (KR) 10-2025-0025531

(51) Int. Cl. H10K 59/80; H10K 59/131

(52) U.S. Cl. CPC H10K 59/873; H10K 59/131

(57) ABSTRACT

A display device and a display panel are provided. A display device according to embodiments of the present disclosure may include a display panel including a display area in which a plurality of subpixels are formed and a non-display area divided into a plurality of inorganic layer areas according to an arrangement of a first inorganic encapsulation layer and a second inorganic encapsulation layer outside the display area and including a plurality of dams, a data driving circuit coupled to a pad area of the display panel, and a timing controller controlling the data driving circuit. In a link area adjacent to the pad area, a distance between the end of a driving voltage line transmitting a driving voltage to the plurality of subpixels and the end of the first inorganic encapsulation layer may be formed to be greater than a distance between the end of the first inorganic encapsulation layer and the outermost first dam.

### CROSS REFERENCE TO RELATED APPLICATION

This application claims priority from Korean Patent Application No. 10-2025-0025531, filed on Feb. 27, 2025, which is hereby incorporated by reference for all purposes as if fully set forth herein.

### BACKGROUND

### Technical Field

Embodiments of the present disclosure relate to a display device and a display panel, and more specifically, to a display device and a display panel capable of preventing moisture penetration defects.

### Description of the Related Art

As examples of display devices for displaying images using digital data, there are a liquid crystal displays (LCD) using liquid crystals and an organic light emitting displays (OLED) using organic light emitting diodes.

Among display devices, the organic light emitting display device utilizes self-luminous light emitting diodes, which provide fast response speeds and have advantages in contrast ratio, luminous efficiency, brightness, and viewing angle. In this case, the light emitting diodes can be implemented as inorganic or organic materials.

The organic light emitting display device may include organic light emitting diodes arranged in each of a plurality of subpixels disposed on a display panel, and may control the brightness of each subpixel by controlling a voltage flowing to the organic light emitting diodes to emit light, thereby displaying images.

Various display devices, including the organic light emitting diode (OLED) display, may experience performance degradation, including reliability, if exposed to moisture.

In particular, if moisture penetrates a link area transmitting the driving signals to a display panel, there may be occurred a defect in the driving signal lines, thereby hindering normal operation of the display device.

### BRIEF SUMMARY

Embodiments of the present disclosure may provide a display device and a display panel capable of preventing moisture from entering a link area that transmits a driving signal to a display panel through a driving circuit.

Embodiments of the present disclosure may provide a display device and a display panel capable of preventing moisture from entering due to a defective seam by positioning an edge portion of a driving signal line formed in the link area inside a dam.

Features of embodiments of the disclosure are not limited to those set forth herein, and other unmentioned features will be apparent to one of ordinary skill in the art from the following description.

A display device according to embodiments of the present disclosure may include a display panel including a display area in which a plurality of subpixels are formed and a non-display area divided into a plurality of inorganic layer areas according to an arrangement of a first inorganic encapsulation layer and a second inorganic encapsulation layer outside the display area and including a plurality of dams, a data driving circuit coupled to a pad area of the display panel, and a timing controller controlling the data driving circuit. In a link area adjacent to the pad area, a distance between the end of a driving voltage line transmitting a driving voltage to the plurality of subpixels and the end of the first inorganic encapsulation layer may be formed to be greater than a distance between the end of the first inorganic encapsulation layer and the outermost first dam among the plurality of dams.

A display panel according to embodiments of the present disclosure may include a display area in which a plurality of subpixels are formed, a non-display area in which a plurality of inorganic layer areas are divided according to an arrangement of a first inorganic encapsulation layer and a second inorganic encapsulation layer outside the display area, and in which a plurality of dams are positioned, a pad area in which a data driving circuit is coupled, and a link area in which a driving voltage line transmitting a driving voltage to the plurality of subpixels extends through the pad area. A distance between the end of a driving voltage line transmitting a driving voltage to the plurality of subpixels and the end of the first inorganic encapsulation layer may be formed to be greater than a distance between the end of the first inorganic encapsulation layer and the outermost first dam among the plurality of dams.

According to embodiments of the present disclosure, it is possible to provide a display device and a display panel capable of preventing moisture from entering a link area that transmits a driving signal to a display panel through a driving circuit.

According to embodiments of the present disclosure, it is possible to provide a display device and a display panel capable of preventing moisture from entering due to a defective seam by positioning an edge portion of a driving signal line formed in the link area inside a dam.

According to embodiments of the present disclosure, it is possible to provide a display device and a display panel capable of preventing moisture from entering the driving signal lines of the link area, thereby achieving the process optimization and a providing a lightweight display device with a narrow bezel.

The effects of the embodiments of the present disclosure are not limited to the foregoing effects, and other effects will be apparent to one of ordinary skill in the art from the following detailed description.

### BRIEF DESCRIPTION OF THE SEVERAL VIEWS OF THE DRAWINGS

The disclosure will be more fully understood from the following detailed description and the accompanying drawings, which are provided for illustration only and are not intended to limit the disclosure.

FIG. 1 schematically illustrates a display device according to embodiments of the present disclosure.

FIG. 2 illustrates a subpixel circuit of a display device according to embodiments of the present disclosure.

FIG. 3 illustrates a cross-section of a display panel according to embodiments of the present disclosure.

FIG. 4 illustrates a plan view of a display device according to embodiments of the present disclosure.

FIG. 5 illustrates a plan view of a display panel in which a first inorganic encapsulation layer and a second inorganic encapsulation layer are formed in a display device according to embodiments of the present disclosure.

FIG. 6 illustrates a cross-section of a first inorganic layer area in a display device according to embodiments of the present disclosure.

FIG. 7 is a plan view illustrating an enlarged view of a second inorganic layer area in a display device according to embodiments of the present disclosure, in which the ends of the first inorganic encapsulation layer and the second inorganic encapsulation layer gradually approach each other.

FIG. 8 illustrates a cross-section taken along section C-D of a second inorganic layer area in a display device according to embodiments of the present disclosure.

FIG. 9 is an enlarged plan view of a third inorganic layer area in a display device according to embodiments of the present disclosure, in which the end positions of the first inorganic encapsulation layer and the end positions of the second inorganic encapsulation layer are identical.

FIG. 10 is an exemplary cross-sectional view taken along the E-F section of the third inorganic layer area in a display device according to embodiments of the present disclosure.

FIG. 11 is an exemplary plan view of a display device according to embodiments of the present disclosure, in which the position of the point where the end positions of the first inorganic encapsulation layer and the end positions of the second inorganic encapsulation layer meet is moved to the outside of the link area.

### DETAILED DESCRIPTION

Hereinafter, some embodiments of the present disclosure will be described in detail with reference to exemplary drawings. In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can”.

Hereinafter, various embodiments of the present disclosure will be described in detail with reference to the accompanying drawings.

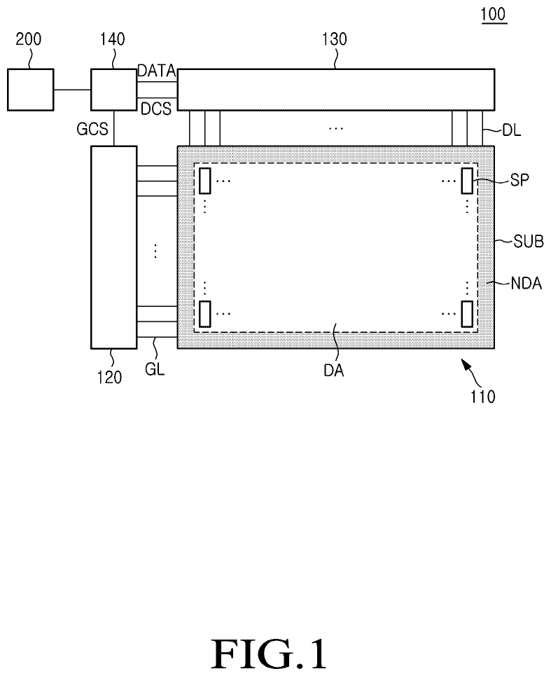

FIG. 1 schematically illustrates a display device according to embodiments of the present disclosure.

Referring to FIG. 1, the display device 100 according to the embodiments of the present disclosure may include a display panel 110 and a display driving circuit for driving the display panel 110.

The display panel 110 may include a display area DA where an image is displayed and a non-display area NDA where an image is not displayed. The non-display area NDA may also be referred to as a bezel area.

The display panel 110 may include a plurality of subpixels SP for displaying an image. For example, a plurality of subpixels SP may be arranged in the display area DA. In some cases, at least one subpixel SP may be arranged in the non-display area NDA. At least one subpixel SP arranged in the non-display area NDA may also be referred to as a dummy subpixel.

The display panel 110 may include a plurality of signal lines for driving a plurality of subpixels SP. For example, the plurality of signal lines may include a plurality of data lines DL and a plurality of gate lines GL. The signal lines may further include a plurality of data lines DL and a plurality of gate lines GL and other signal lines, depending on the structure of the subpixel SP. For example, the other signal lines may include a driving voltage line and a reference voltage line.

The plurality of data lines DL and the plurality of gate lines GL may intersect each other. Each of the plurality of data lines DL may be arranged to extend in a first direction. Each of the plurality of gate lines GL may be arranged to extend in a second direction. Here, the first direction may be a column direction and the second direction may be a row direction. In this disclosure, the column direction and the row direction are relative. For example, the column direction may be a vertical direction and the row direction may be a horizontal direction. For another example, the column direction may be a horizontal direction and the row direction may be a vertical direction.

The driving circuit may include a data driving circuit 130 for driving a plurality of data lines DL and a gate driving circuit 120 for driving a plurality of gate lines GL. The driving circuit may further include a timing controller 140 for controlling the data driving circuit 130 and the gate driving circuit 120.

The data driving circuit 130 is a circuit for driving a plurality of data lines DL and may output a data signal (also called a data voltage) corresponding to an image signal to a plurality of data lines DL. The gate driving circuit 120 is a circuit for driving a plurality of gate lines GL, and may generate gate signals and output the gate signals to a plurality of gate lines GL. The gate signal may include one or more scan signals and a light emission signal.

The timing controller 140 may start a scan according to the timing implemented in each frame and control the data driving at an appropriate time according to the scan. The timing controller 140 may convert input image data input from the outside into a data signal format used by the data driving circuit 130, and supply the converted image data DATA to the data driving circuit 130.

The timing controller 140 may receive display driving control signals from an external host system 200 along with input image data. For example, the display driving control signals may include a vertical synchronization signal, a horizontal synchronization signal, an input data enable signal, a clock signal, etc.

The timing controller 140 may generate a data driving control signal DCS and a gate driving control signal GCS based on the display driving control signals input from the host system 200. The timing controller 140 may control the driving operation and driving timing of the data driving circuit 130 by supplying the data driving control signal DCS to the data driving circuit 130. The timing controller 140 may control the driving operation and driving timing of the gate driving circuit 120 by supplying a gate driving control signal GCS to the gate driving circuit 120.

The data driving circuit 130 may include one or more source driving integrated circuits SDIC. Each source driving integrated circuit may include a shift register, a latch circuit, a digital to analog converter DAC, an output buffer, etc. Each source driving integrated circuit may further include an analog to digital converter ADC, depending on the case.

For example, each source driving integrated circuit may be connected to the display panel 110 in a tape-automated-bonding (TAB) manner, may be connected to a bonding pad of the display panel 110 in a chip-on-glass (COG) or chip-on-panel (COP) manner, or implemented in a chip-on-film (COF) manner and connected to the display panel 110.

The gate driving circuit 120 may output a gate signal of a turn-on level voltage or a gate signal of a turn-off level voltage under the control of the timing controller 140. The gate driving circuit 120 may sequentially drive a plurality of gate lines GL by sequentially supplying gate signals of a turn-on level voltage to a plurality of gate lines GL.

The gate driving circuit 120 may include one or more gate driving integrated circuits GDIC.

The gate driving circuit 120 may be connected to the display panel 110 in a tape-automated-bonding (TAB) manner, connected to a bonding pad of the display panel 110 in a chip-on-glass (COG) or chip-on-panel (COP) manner, or connected to the display panel 110 in a chip-on-film (COF) manner. Alternatively, the gate driving circuit 120 may be formed in a non-display area NDA of the display panel 110 in a gate-in-panel (GIP) type. The gate driving circuit 120 may be disposed on or connected to the substrate. That is, the gate driving circuit 120 may be disposed in a non-display area NDA of the substrate in the case of the gate-in-panel (GIP) type. The gate driving circuit 120 may be connected to the substrate if it is a chip-on-glass (COG) type or a chip-on-film (COF) type.

Meanwhile, at least one of the data driving circuit 130 and the gate driving circuit 120 may be disposed in the display area DA. For example, at least one of the data driving circuit 130 and the gate driving circuit 120 may be disposed so as not to overlap with the subpixels SP, or may be disposed so as to partially or completely overlap with the subpixels SP.

The data driving circuit 130 may be connected to one side (e.g., the upper side or the lower side) of the display panel 110. Depending on the driving method, the panel design method, etc., the data driving circuit 130 may be connected to both sides (e.g., the upper side and the lower side) of the display panel 110, or may be connected to two or more sides among the four sides of the display panel 110.

The gate driving circuit 120 may be connected to one side (e.g., left or right) of the display panel 110. Depending on the driving method, panel design method, etc., the gate driving circuit 120 may be connected to both sides (e.g., left and right) of the display panel 110, or may be connected to two or more of the four sides of the display panel 110.

The timing controller 140 may be implemented as a separate component from the data driving circuit 130, or may be implemented as an integrated circuit by being integrated with the data driving circuit 130. The timing controller 140 may be a controller used in a typical display technology, or may be a control device that can perform other control functions including the timing controller 140, or may be a circuit within the control device. The timing controller 140 may be implemented with various circuits or electronic components such as an integrated circuit (IC), a field programmable gate array (FPGA), an application specific integrated-circuit (ASIC), or a processor.

The timing controller 140 may be mounted on a printed circuit board or a flexible printed circuit, and may be electrically connected to the data driving circuit 130 and the gate driving circuit 120 through the printed circuit board or the flexible printed circuit. The timing controller 140 may transmit and receive signals with the data driving circuit 130 according to one or more predefined interfaces. Here, for example, the interface may include a low voltage differential signaling (LVDS) interface, an EPI interface, a serial peripheral SP interface, etc.

The display device 100 according to the embodiments of the present disclosure may be a self-luminous display device in which the display panel 110 emits light by itself. If the display device 100 according to embodiments of the present disclosure is a self-luminous display device, each of the plurality of subpixels SP may include a light emitting device. For example, the display device 100 according to embodiments of the present disclosure may be an organic light emitting display device in which the light emitting device is implemented as an organic light emitting diode (OLED). For another example, the display device 100 according to embodiments of the present disclosure may be an inorganic light emitting display device in which the light emitting device is implemented as an inorganic-based light emitting diode. For another example, the display device 100 according to embodiments of the present disclosure may be a quantum dot display device in which the light emitting device is implemented as a quantum dot, which is a semiconductor crystal that emits light by itself.

In this case, each subpixel SP arranged on the display panel 110 within the display device 100 may be composed of a light emitting device and circuit elements such as a driving transistor for driving the light emitting device.

The type and number of circuit elements constituting each subpixel SP may be determined in various ways depending on the provided function and design method.

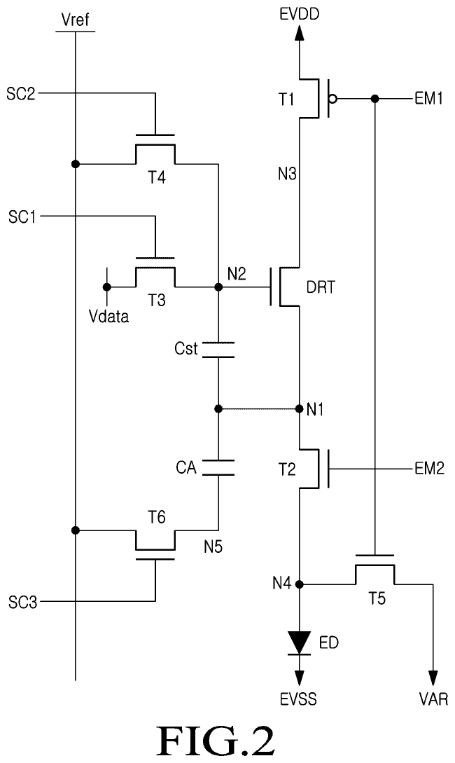

FIG. 2 illustrates a subpixel circuit of a display device according to embodiments of the present disclosure.

Referring to FIG. 2, a subpixel circuit of a display device 100 according to embodiments of the present disclosure may include a light emitting device ED, a driving transistor DRT for driving the light emitting device ED, a plurality of switching transistors T1 to T6, and a plurality of capacitors Cst and CA.

The subpixel circuit may be driven in the following order: an initialization period, a sensing period, a data writing period, an anode reset period, and a emission period.

The subpixel circuit may be connected to a data line DL to which a data voltage Vdata is applied, and gate lines to which gate signals (e.g., EM1, EM2, SC1, SC2, SC3) are applied.

In addition, the subpixel circuit may be connected to a pixel high-potential voltage line to which a pixel high-potential voltage EVDD is applied, a pixel low-potential voltage line to which a pixel low-potential voltage EVSS is applied, a reset voltage line to which a reset voltage VAR is applied, and a reference voltage line to which a reference voltage Vref is applied.

All subpixels SP arranged on the display panel 110 may be connected to a common constant voltage line. In this case, the levels of the constant voltages EVDD, EVSS, VAR, and Vref applied to the subpixel circuit may be set in consideration of the voltage margin in the saturation area of the driving transistor DRT. For example, the levels of the constant voltages EVDD, EVSS, VAR, and Vref may be set under the condition of EVDD>Vref>VAR>EVSS.

The gate signals EM1, EM2, SC1, SC2, and SC3 may include pulses that swing between a gate high voltage at a turn-on level and a gate low voltage at a turn-off level. The gate high voltage may be set to a voltage level higher than a pixel high-potential voltage EVDD, and the gate low voltage may be set to a voltage level lower than a pixel low-potential voltage EVSS.

The gate signals may include a first emission signal EM1, a second emission signal EM2, a first scan signal SC1, a second scan signal SC2, and a third scan signal SC3. The first emission signal EM1 may be referred to as a first gate signal, the second emission signal EM2 may be referred to as a second gate signal, the first scan signal SC1 may be referred to as a third gate signal, the second scan signal SC2 may be referred to as a fourth gate signal, and the third scan signal SC3 may be referred to as a fifth gate signal.

The driving transistor DRT may generate current according to a gate-source voltage to drive the light emitting device ED. The driving transistor DRT may include a first electrode connected to a first node N1, a gate electrode connected to a second node N2, and a second electrode connected to a third node N3.

The light emitting device ED may be implemented as an organic light emitting diode (OLED). The light emitting device ED may include an anode electrode, a cathode electrode, and an organic compound layer formed between the electrodes. The anode electrode of the light emitting device ED may be connected to a fourth node N4, and the cathode electrode may be connected to a pixel low-potential voltage line to which a pixel low-potential voltage EVSS is applied.

The organic compound layer may include, but is not limited to, a hole injection layer HIL, a hole transport layer HTL, an emission layer EML, an electron transport layer ETL, and an electron injection layer EIL.

If a voltage is applied to the anode and cathode electrodes of the light emitting device ED, holes passing through the hole transport layer HTL and electrons passing through the electron transport layer ETL move to the emission layer EML to generate excitons. Visible light is emitted from the emission layer EML. The light emitting device ED may be implemented in a tandem structure in which multiple emission layers are stacked. The light emitting device ED of the tandem structure can improve the brightness and lifespan of the subpixel.

A first capacitor Cst may be connected between the first node N1 and the second node N2. The first capacitor Cst may be initialized during an initialization period and then may store the threshold voltage of the driving transistor DRT during a sensing period. The first capacitor Cst may store a data voltage Vdata compensated for by the threshold voltage of the driving transistor DRT during a data write period and then may maintain the gate-source voltage of the driving transistor DRT during the anode reset period and the emission period.

A second capacitor CA may be connected between the first node N1 and a sixth switching transistor T6. The second capacitor CA may be charged to the reference voltage Vref when the sixth switching transistor T6 is turned on, thereby maintaining the first node N1 at the reference voltage Vref.

A first switching transistor T1 may be connected between the pixel high-potential voltage line to which the pixel high-potential voltage EVDD is applied and the third node N3 of the driving transistor DRT, and may be turned on in response to the first emission signal EM1. If the first switching transistor T1 is turned on, the pixel high-potential voltage EVDD may be applied to the third node N3. The first switching transistor T1 may be formed as a P-type transistor, and may be turned on when the voltage of the first emission signal EM1 is a gate low voltage.

A second switching transistor T2 may be connected between the first node N1 and the fourth node N4, and may be turned on in response to the second emission signal EM2. If the second switching transistor T2 is turned on, the first node N1 may be connected to the fourth node N4. The second switching transistor T2 may be formed as an N-type transistor and may be turned on when the second emission signal EM2 is at a high gate voltage.

A third switching transistor T3 may be connected between a data line to which a data voltage Vdata is applied and a second node N2, and may be turned on in response to a first scan signal SC1. If the third switching transistor T3 is turned on, the data voltage Vdata may be applied to the second node N2 of the driving transistor DRT. The third switching transistor T3 may be formed as an N-type transistor and may be turned on when the first scan signal SC1 is at a high gate voltage.

A fourth switching transistor T4 may be connected between a reference voltage line to which a reference voltage Vref is applied and a second node N2 of the driving transistor DRT, and may be turned on in response to a second scan signal SC2. If the fourth switching transistor T4 is turned on, the reference voltage Vref may be applied to the second node N2. The fourth switching transistor T4 may be formed as an N-type transistor, and may be turned on when the voltage of the second scan signal SC2 is a gate high voltage.

A fifth switching transistor T5 may be connected between the reset voltage line to which the reset voltage VAR is applied and the fourth node N4, and may be turned on in response to the first emission signal EM1. If the fifth switching transistor T5 is turned on, the reset voltage VAR may be applied to the fourth node N4. The fifth switching transistor T5 may be formed as an N-type transistor, and may be turned on when the voltage of the first emission signal EM1 is a gate high voltage.

A sixth switching transistor T6 may be connected between a reference voltage line to which a reference voltage Vref is applied and the second capacitor CA, and may be turned on in response to the third scan signal SC3. If the sixth switching transistor T6 is turned on, the reference voltage Vref may be charged into the second capacitor CA. The sixth switching transistor T6 may be formed as an N-type transistor, and may be turned on when the voltage of the third scan signal SC3 is a gate high voltage.

This subpixel circuit can be driven in the following order: an initialization period, a sensing period, a data writing period, an anode reset period, and a emission period.

As described above, in the subpixel circuit according to the embodiments of the present disclosure, the first switching transistor T1 may be a P-type transistor, and the second to sixth switching transistors T2 to T6 and the driving transistor DRT may be N-type transistors.

If the first switching transistor T1 is formed of a P-type transistor, the third node N3 can be fixed to the pixel high-potential voltage EVDD, so there is an advantage in that the light emitting current flowing to the light emitting device ED does not fluctuate due to the storage capacitor Cst. Therefore, it is easy to supply the light emitting current stably.

The P-type transistor may be a silicon transistor formed from a semiconductor such as silicon (for example, a transistor having a polysilicon channel formed using a low temperature process referred to as LTPS or low temperature polysilicon).

Meanwhile, the N-type transistor may be formed using an oxide semiconductor (e.g., a transistor having a channel formed from an oxide semiconductor such as indium, gallium, zinc oxide, IGZO, or IGZTO). Oxide transistors have the characteristic of relatively low leakage current compared to silicon transistors.

Therefore, the driving transistor DRT and at least some of the switching transistors T2 to T6 constituting the subpixel circuit may be formed using oxide transistors. If the driving transistor DRT and switching transistor are implemented using oxide transistors, current leakage from the driving transistor DRT can be prevented, thereby reducing image quality defects such as flicker.

In this case, in order to detect the flicker characteristics of the oxide transistors DRT, and T2 to T6, a test transistor may be used to accurately detect the interface characteristics of a buffer layer through a lower gate electrode and the interface characteristics of a gate insulating film through an upper gate electrode.

Here, the driving transistor DRT and switching transistors T1 to T6 constituting the subpixel circuit may be referred to as subpixel transistors.

A subpixel SP composed of seven transistors DRT and T1 to T6 and two storage capacitors Cst and CA may be referred to as a 7T2C structure.

Here, the 7T2C structure is illustrated as an example among various structures of subpixel SP circuits, and the structure and number of transistors and capacitors constituting the subpixel SP may vary. Meanwhile, each of the plurality of subpixels SP may have the same structure, or some of the plurality of subpixels SP may have different structures.

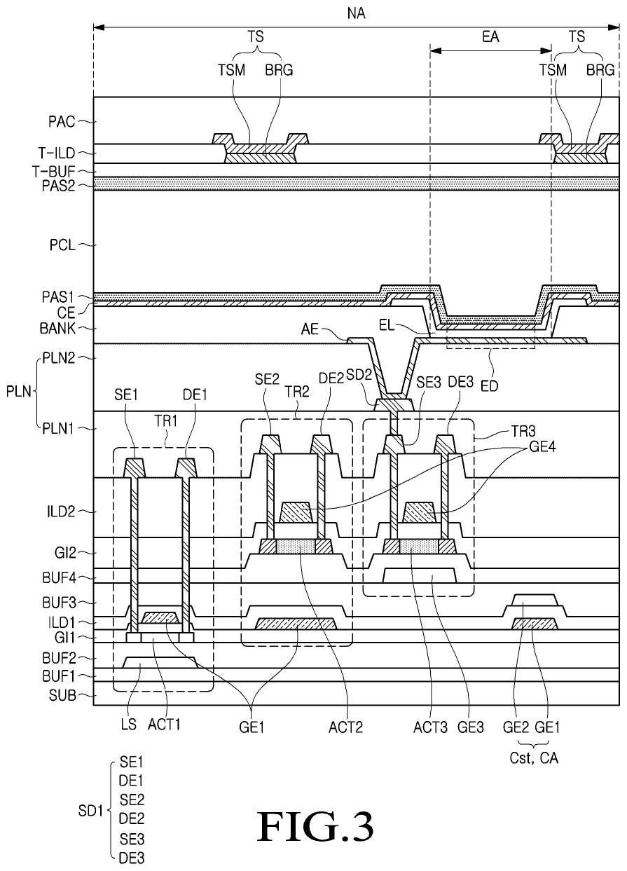

FIG. 3 illustrates a cross-section of a display panel according to embodiments of the present disclosure.

Referring to FIG. 3, a display panel 110 according to embodiments of the present disclosure may have a first buffer layer BUF1 formed on a substrate SUB.

A light shield layer LS for blocking light may be formed on the first buffer layer BUF1.

A second buffer layer BUF2 may be disposed to cover the light shield layer LS.

A first active layer ACT1 constituting a first transistor TR1 may be disposed on the second buffer layer BUF2.

The first transistor TR1 may include a low temperature polysilicon transistor among the switching transistors constituting the subpixel SP. For example, the subpixel of FIG. 2 may include a first switching transistor T1.

A first gate insulating film GI1 may be disposed on the first active layer ACT1.

A first gate electrode GE1 made of a gate material may be formed on the first gate insulating film GI1. The gate material may be an opaque conductive material with low resistance, such as aluminum (Al), aluminum alloy, tungsten (W), copper (Cu), nickel (Ni), chromium (Cr), molybdenum (Mo), titanium (Ti), platinum (Pt), or tantalum (Ta). Alternatively, the gate material may be formed as a multilayer structure in which transparent conductive materials, such as indium-tin oxide (ITO) or indium-zinc oxide (IZO), and opaque conductive materials are stacked.

The first gate electrode GE1 may correspond to a gate electrode of the first transistor TR1 and may correspond to a lower gate electrode of a second transistor TR2 formed at a position spaced apart from the first transistor TR1. In addition, the first gate electrode GE1 may correspond to one electrode forming a capacitor Cst and CA.

For example, the second transistor TR2 may be a switching transistor formed of an oxide transistor in a subpixel. In the subpixel of FIG. 2, the second transistor TR2 may correspond to the second switching transistor T2 to the sixth switching transistor T6.

In this case, the second transistor TR2 may be formed with a dual gate structure including an upper gate electrode and a lower gate electrode. In this case, the first gate electrode GE1 may correspond to the lower gate electrode of the second transistor TR2.

A first interlayer insulating film ILD1 may be disposed to cover the first gate electrode GE1.

Meanwhile, a second gate electrode GE2 forming a capacitance with the first gate electrode GE1 may be formed on the first interlayer insulating film ILD1. The second gate electrode GE2 may be formed of the same gate material as the first gate electrode GE1, and a capacitor (e.g., Cst or CA) of the subpixel circuit may be formed by the first gate electrode GE1 and the second gate electrode GE2.

A third buffer layer BUF3 may be formed on the first interlayer insulating film ILD1.

A third gate electrode GE3 formed of a gate material may be formed on the third buffer layer BUF3.

The third gate electrode GE3 may correspond to a lower gate electrode of a third transistor TR3 formed at a position spaced apart from the second transistor TR2.

For example, the third transistor TR3 may be a driving transistor DRT formed of an oxide transistor in the subpixel.

In this case, the third transistor TR3 may be formed with a dual gate structure including an upper gate electrode and a lower gate electrode. In this case, the third gate electrode GE3 may correspond to the lower gate electrode of the third transistor TR3.

In this way, the second transistor TR2 and the third transistor TR3, which are formed of oxide transistors, may include lower gate electrodes GE1 and GE3 positioned on different layers in a vertical direction.

A fourth buffer layer BUF4 may be disposed to cover the third gate electrode GE3 on the third buffer layer BUF3.

A second active layer ACT2 constituting the second transistor TR2 and a third active layer ACT3 constituting the third transistor TR3 may be disposed on the fourth buffer layer BUF4.

The second active layer ACT2 may constitute an active layer of a switching transistor formed of an oxide transistor, and the third active layer ACT3 may constitute an active layer of a driving transistor formed of an oxide transistor.

A second gate insulating film GI2 may be disposed to cover the second active layer ACT2 and the third active layer ACT3.

Two or more fourth gate electrodes GE4 formed of a gate material may be formed on the second gate insulating film GI2.

The fourth gate electrodes GE4 may correspond to the upper gate electrodes of the second transistor TR2 and the upper gate electrodes of the third transistor TR3.

A second interlayer insulating film ILD2 may be disposed to cover the fourth gate electrode GE4.

A plurality of first source-drain electrode patterns SD1 may be disposed on the second interlayer insulating film ILD2.

The first source-drain electrode patterns SD1 may be formed using any one of molybdenum (Mo), titanium (Ti), tantalum (Ta), tungsten (W), copper (Cu), chromium (Cr), aluminum (Al), and an alloy formed from a combination thereof.

One of the first source-drain electrode patterns SD1 may correspond to a first source electrode SE1 and a first drain electrode DE1 of the first transistor TR1. Furthermore, another of the first source-drain electrode patterns SD1 may correspond to a second source electrode SE2 and a second drain electrode DE2 of the second transistor TR2. Additionally, another one of the first source-drain electrode patterns SD1 may correspond to a third source electrode SE3 and a third drain electrode DE3 of the third transistor TR3.

A portion of the first source-drain electrode pattern SD1 may be electrically connected to the second active layer ACT2 of the second transistor TR2 and the third active layer ACT3 of the third transistor TR3 through contact holes of the second interlayer insulating film ILD2 and the second gate insulating film GI2, respectively.

In addition, another part of the first source-drain electrode pattern SD1 may be electrically connected to the first active layer ACT1 of the first transistor TR1 through contact holes of the second interlayer insulating film ILD2, the second gate insulating film GI2, the fourth buffer layer BUF4, the third buffer layer BUF3, the first interlayer insulating film ILD1, and the first gate insulating film GI1.

A first planarization layer PLN1 may be disposed to cover the first source-drain electrode pattern SD1. The first planarization layer PLN1 may be made of an organic insulating material, such as an acrylic resin. In this case, the driving transistor DRT and some switching transistors (e.g., T2 to T6) constituting the subpixel SP may be formed with a dual gate structure including an upper gate electrode and a lower gate electrode to improve current characteristics in a turn-on state and secure reliability.

A second source-drain electrode pattern SD2 may be arranged on the first planarization layer PLN1. The second source-drain electrode pattern SD2 may be connected to one of the first source-drain electrode patterns SD1 through a contact hole of the first planarization layer PLN1.

A second planarization layer PLN2 may be disposed to cover the second source-drain electrode pattern SD2. A light emitting device ED may be disposed on the second planarization layer PLN2.

The light emitting device ED may include an anode electrode AE, an emission layer EL, and a cathode electrode CE.

The anode electrode AE may be disposed on the second planarization layer PLN2. The anode electrode AE may be electrically connected to the second source-drain electrode pattern SD2 through a contact hole of the second planarization layer PLN2.

A bank BANK may be disposed to cover a portion of the anode electrode AE. A portion of the bank BANK corresponding to the emission area EA of the subpixel SP may be open.

A portion of the anode electrode AE may be exposed through an opening (e.g., open portion) of the bank BANK.

An emission layer EL may be positioned on the side of the bank and in the opening (or open portion) of the bank. All or part of the emission layer EL may be positioned between adjacent banks. The emission layer EL may include an organic film.

In the opening of the bank BANK, the emission layer EL may contact the anode electrode AE. A cathode electrode CE may be disposed on the emission layer EL.

An encapsulation layer ENCAP may be disposed on the light emitting device ED.

The encapsulation layer ENCAP may have a single-layer structure or a multi-layer structure. For example, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic films, and the second encapsulation layer PCL may be an organic film. Among the first encapsulation layer PAS1, the second encapsulation layer PCL, and the third encapsulation layer PAS2, the second encapsulation layer PCL may be the thickest. Accordingly, the second encapsulation layer PCL may function as a planarization layer.

The first encapsulation layer PAS1 may be referred to as a first inorganic encapsulation layer, the second encapsulation layer PCL may be referred to as an organic encapsulation layer, and the third encapsulation layer PAS2 may be referred to as a second inorganic encapsulation layer.

The first encapsulation layer PAS1 may be disposed on the cathode electrode CE and may be disposed closest to the light emitting device ED. The first encapsulation layer PAS1 may be formed of an inorganic insulating material capable of low temperature deposition. For example, the first encapsulation layer PAS1 may be formed of silicon nitride (SiNx), silicon oxide (SiOx), silicon oxynitride (SiON), or aluminum oxide (Al2O3). Since the first encapsulation layer PAS1 is deposited in a low temperature atmosphere, the first encapsulation layer PAS1 can prevent damage to the emission layer EL containing an organic material vulnerable to high-temperature atmosphere during the deposition process.

The second encapsulation layer PCL may be formed with a smaller area than the first encapsulation layer PAS1. In this case, the second encapsulation layer PCL may be formed to expose both ends of the first encapsulation layer PAS1. The second encapsulation layer PCL may act as a buffer to alleviate stress between layers due to warping of the display device 100, and may also enhance the planarizing performance.

For example, the second encapsulation layer PCL may be formed of an acrylic resin, an epoxy resin, a polyimide, polyethylene, or silicon oxycarbon (SiOC), and may be formed of an organic insulating material. For example, the second encapsulation layer PCL may be formed using an inkjet method.

The third encapsulation layer PAS2 may be formed on the second encapsulation layer PCL to cover the upper and side surfaces of the second encapsulation layer PCL and the first encapsulation layer PAS1, respectively. The third encapsulation layer PAS2 may minimize or block the penetration of external moisture or oxygen into the first encapsulation layer PAS1 and the second encapsulation layer PCL.

For example, the third encapsulation layer PAS2 may be formed of an inorganic insulating material, such as silicon nitride (SiNx), silicon oxide (SiOx), silicon oxynitride (SiON), or aluminum oxide (Al2O3).

Meanwhile, the display device 100 of the present disclosure may have a touch sensor TS formed on the encapsulation layer ENCAP to detect a touch from a user's finger or pen.

If the touch sensor TS is of the type built into the display panel 110, the touch sensor TS may be disposed on the encapsulation layer ENCAP. The touch sensor structure is described in detail below.

A touch buffer layer T-BUF may be disposed on the encapsulation layer ENCAP.

The touch sensor TS may be disposed on the touch buffer layer T-BUF.

The touch sensor TS may include a touch sensor metal TSM and a bridge metal BRG positioned on different layers.

The touch sensor metal TSM and the bridge metal BRG may have a triple-layer structure of Ti/Al/Ti.

A touch interlayer dielectric T-ILD may be positioned between the touch sensor metal TSM and the bridge metal BRG.

The touch interlayer dielectric T-ILD may be formed of an inorganic material such as silicon nitride (SiNx) or silicon oxide (SiOx). In this case, the touch interlayer dielectric T-ILD may be formed of an inorganic material such as silicon oxide (SiOx) to improve touch performance.

For example, the touch sensor TS may include a first touch sensor metal, a second touch sensor metal, and a third touch sensor metal, which are positioned adjacent to each other.

If the third touch sensor metal is positioned between the first touch sensor metal and the second touch sensor metal, and the first and second touch sensor metals are to be electrically connected to each other, the first and second touch sensor metals may be electrically connected to each other via a bridge metal BRG located on a different layer.

The bridge metal BRG may be insulated from the third touch sensor metal by a touch interlayer insulating film T-ILD.

If the touch sensor TS is formed on a display panel 110, chemicals (such as a developer or etchant) used in the process or moisture may be generated from the outside.

By positioning the touch sensor TS on a touch buffer film T-BUF, chemicals or moisture can be prevented from penetrating into the emission layer EL containing an organic material during the manufacturing process of the touch sensor TS.

Accordingly, the touch buffer film T-BUF can prevent damage to the emission layer EL that is vulnerable to chemicals or moisture.

The touch buffer film T-BUF may be formed at a low temperature (e.g., 100 degrees Celsius) or lower and may be formed of an organic insulating material with a low dielectric constant, in order to prevent damage to the emission layer EL that includes an organic material vulnerable to high temperatures. For example, the touch buffer film T-BUF may be formed of an acrylic material, an epoxy material, or a siloxane material.

The display device 100 may be damaged by bending, resulting in damage to the encapsulation layer ENCAP, and the touch sensor metal TSM positioned on the touch buffer film T-BUF. Even if the display device 100 is bent, the touch buffer film T-BUF with planarization performance made of an organic insulating material can prevent damage to the encapsulation layer ENCAP or damage to the touch sensor metal TSM or the bridge metal BRG.

A protection layer PAC may be disposed to cover the touch sensor TS. The protection layer PAC may be an organic insulating film.

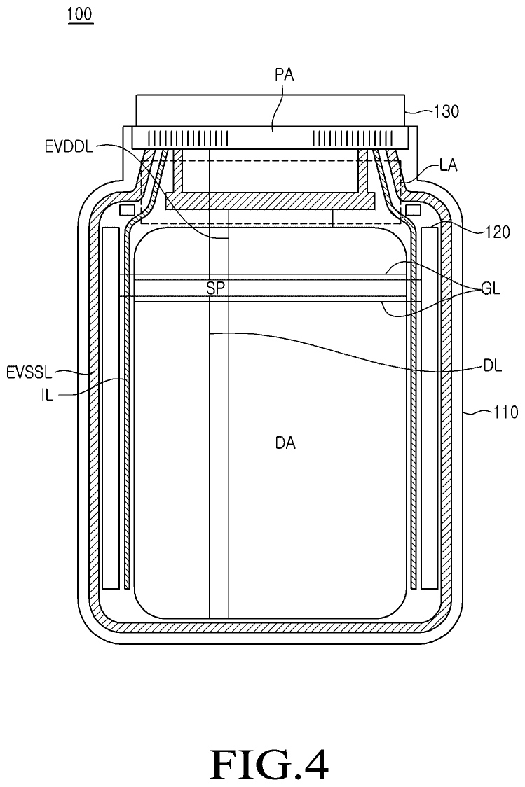

FIG. 4 illustrates an example of a plan view of a display device according to embodiments of the present disclosure.

Referring to FIG. 4, a display device 100 according to embodiments of the present disclosure may include at least one display area DA, and a plurality of subpixels SP may be arranged in the display area DA.

A non-display area NDA may be disposed around the display area DA. The non-display area NDA may be adjacent to one or more side surfaces of the display area DA and surround the rectangular display area DA. However, the shape of the display area DA and the shape and arrangement of the non-display area NDA adjacent to the display area DA are not limited thereto.

The gate driving circuit 120 may be disposed in the side non-display area NDA of the display panel 110, and the data driving circuit 130 may be disposed in the upper non-display area NDA.

In the display area DA, a plurality of subpixels SP connected to the plurality of data lines DL and the plurality of gate lines GL may be arranged at locations where the plurality of data lines DL and the plurality of gate lines GL intersect.

The non-display area NDA may include a pad area PA and a link area LA where the data driving circuit 130 and the display panel 110 come into contact.

The pad area PA may include various signal lines or pads connected to the data driving circuit 130. The pad area PA may include pads for applying external signals to the display panel, such as probe pads for lighting inspection and pads for bonding.

The link area LA may include various connection lines and driving voltage lines EVDDL and EVSSL arranged between the pad area PA and the display area DA.

The driving voltage line may include a pixel high-potential voltage line EVDDL that applies a high-level pixel high-potential voltage EVDD to the subpixel SP and a pixel low-potential voltage line EVSSL that applies a low-level pixel low-potential voltage EVSS.

The driving voltage lines EVDDL and EVSSL may be formed using a first source-drain electrode pattern SD1 or a second source-drain electrode pattern SD2.

The pixel low-potential voltage line EVSSL may apply a common voltage to the subpixel SP and may be arranged to surround three sides of the display area DA between the gate driving circuit 120 and an edge of the display panel 110.

Additionally, an initialization line IL for applying an initialization voltage to the subpixel SP may be positioned between the display area DA and the gate driving circuit 120.

The data driving circuit 130 may be mounted on a printed circuit board and connected to the display panel 110 via the pad area PA, or may be mounted in a COP (Chip-On-Panel) form in the link area LA between the pad area PA and the display area DA.

The subpixel SP of the display area DA may include a subpixel circuit connected to a gate line GL and a data line DL and operating in response to a data voltage. The subpixel circuit may be positioned to overlap with the data line DL or the gate line GL.

Depending on the configuration of the subpixel circuit, the subpixel SP may be implemented to include an organic light emitting device. When a subpixel SP includes an organic light emitting device, the display panel 110 may be implemented in a top emission method, a bottom emission method, or a dual emission method.

In this case, the outer area of the display panel 110 may implement a narrow bezel, and a first inorganic encapsulation layer PAS1 and a second inorganic encapsulation layer PAS2 constituting an encapsulation layer ENCAP may extend from the display area DA to prevent moisture penetration.

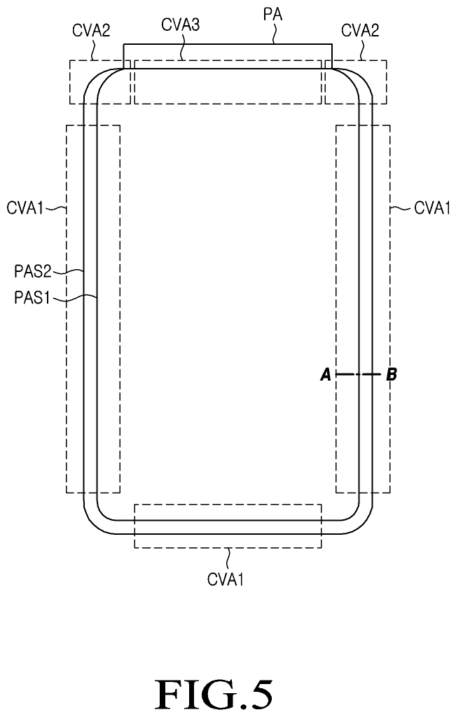

FIG. 5 illustrates a plan view of a display panel on which a first inorganic encapsulation layer and a second inorganic encapsulation layer are formed in a display device according to embodiments of the present disclosure.

Referring to FIG. 5, in order to minimize or block the penetration of moisture or oxygen from the outside into the display device 100 according to embodiments of the present disclosure, an inorganic encapsulation layer PAS1 and PAS2 may be formed from the display area of the display panel 110 to the outer bezel area.

In the display area, a first inorganic encapsulation layer PAS1, an organic encapsulation layer PCL, and a second inorganic encapsulation layer PAS2 may be formed in a stacked structure. Meanwhile, in the bezel area, the first inorganic encapsulation layer PAS1 and the second inorganic encapsulation layer PAS2 may extend.

In this case, the end of the second inorganic encapsulation layer PAS2 may be located outside the end of the first inorganic encapsulation layer PAS1, or the end of the first inorganic encapsulation layer PAS1 and the end of the second inorganic encapsulation layer PAS2 may be formed at the same position.

For example, the bezel area opposite the pad area PA where the data driving circuit 130 is coupled to the display panel 110 and the bezel areas on the left and right sides of the display panel 110 may be referred to as a first inorganic layer area CVA1 in which the end of the second inorganic encapsulation layer PAS2 extends further than the end of the first inorganic encapsulation layer PAS1.

Meanwhile, the portion parallel to the pad area PA may be referred to as a third inorganic layer area CVA3 in which the end of the first inorganic encapsulation layer PAS1 and the end of the second inorganic encapsulation layer PAS2 are formed at the same position.

On the other hand, the portion where the first inorganic layer area CVA1 and the third inorganic layer area CVA3 meet may correspond to a second inorganic layer area CVA2 in which the end of the first inorganic encapsulation layer PAS1 and the end of the second inorganic encapsulation layer PAS2 gradually approach each other. In this case, the second inorganic layer area CVA2 may be located on both outer sides of the pad area PA.

In this way, since the positions of the end of the first inorganic encapsulation layer PAS1 and the end of the second inorganic encapsulation layer PAS2 are different for each of the inorganic layer areas CVA1, CVA2, and CVA3, the separation distance of the driving voltage lines EVDDL and EVSSL extending along the inorganic layer areas CVA1, CVA2, and CVA3 may vary.

In this case, if the distance between the first inorganic encapsulation layer PAS1 and the driving voltage line EVDDL and EVSSL is close, there is a high possibility that moisture flowing in from the end or seam area of the first inorganic encapsulation layer PAS1 is transmitted to the driving voltage line EVDDL and EVSSL of the link area, which may cause a malfunction.

Therefore, in the display device 100 of the present disclosure, the end of the driving voltage line EVDDL and EVSSL may be disposed to be located below the insulating film inside the dam formed in the inorganic layer area CVA1, CVA2, and CVA3, thereby maintaining a constant distance from the end of the first inorganic encapsulation layer PAS1 and preventing a malfunction due to moisture penetration.

In this case, the end positions of the driving voltage lines EVDDL and EVSSL may be the same for each inorganic layer area CVA1, CVA2, and CVA3, or may vary depending on the end position of the first inorganic encapsulation layer PAS1 in each inorganic layer area CVA1, CVA2, and CVA3.

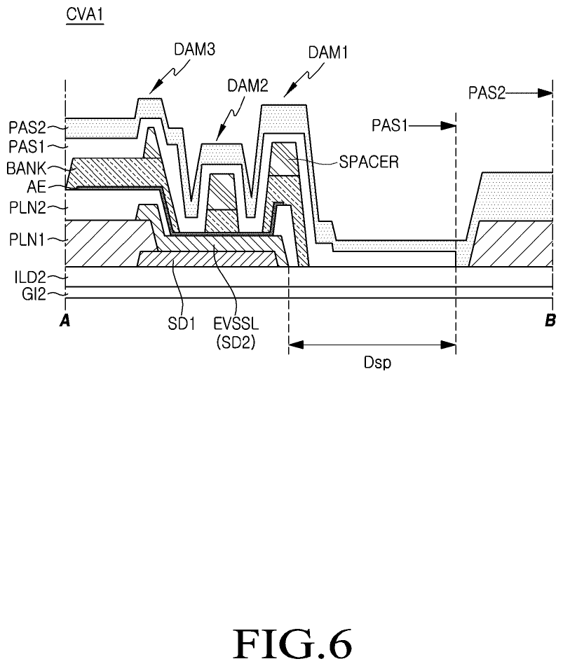

FIG. 6 illustrates an example of a cross-section of a first inorganic layer area in a display device according to embodiments of the present disclosure.

Here, the first inorganic layer area CVA1 represents a cross-section taken along section A-B of FIG. 5.

Referring to FIG. 6, in the display device 100 according to embodiments of the present disclosure, the end of the second inorganic encapsulation layer PAS2 in the first inorganic layer area CVA1 may extend further outward than the end of the first inorganic encapsulation layer PAS1.

In this case, one or more dams may be formed in the first inorganic layer area CVA1 to prevent the liquid-type organic encapsulation layer PCL from collapsing toward the bezel area when formed in the display area DA.

Here, it is exemplified a case where a first dam DAM1, a second dam DAM2, and a third dam DAM3 are formed.

The first dam DAM1 is the outermost dam, and may have a structure in which a second planarization layer PLN2, a bank BANK, a spacer SPACER, a first inorganic encapsulation layer PAS1, and a second inorganic encapsulation layer PAS2 are sequentially stacked.

In this case, the end of the second source-drain electrode pattern SD2 forming the driving voltage line may be located below the second planarization layer PLN2 inside the first dam DAM1. Here, the pixel low-potential voltage line EVSSL transmitting the pixel low-potential voltage EVSS among the driving voltage lines is shown as an example. That is, the pixel low-potential voltage line EVSSL may extend only to the inside of the first dam DAM1 located at the outermost end of the first inorganic layer area CVA1, and may not extend outside the first dam DAM1.

As a result, a separation distance Dsp between the end of the pixel low-potential voltage line EVSSL and the end of the first inorganic encapsulation layer PAS1 may increase. In addition, since no other metal wiring is located within the separation distance Dsp other than the pixel low-potential voltage line EVSSL, the thickness of the first inorganic encapsulation layer PAS1 that passes over the first dam DAM1 can be increased. Through this, moisture flowing in from the upper portion of the inorganic encapsulation layers PAS1 and PAS2 can be effectively blocked from being transmitted to the pixel low-potential voltage line EVSSL in the link area.

For example, the separation distance Dsp between the end of the pixel low-potential voltage line EVSSL and the end of the first inorganic encapsulation layer PAS1 may be maintained at 60 um or more, but is not limited thereto.

In this case, the end of the pixel low-potential voltage line EVSSL may be arranged to be covered by the second planarization layer PLN2 inside the first dam DAM1, thereby effectively blocking moisture from flowing into the link area.

The second dam DAM2 may be located inwardly adjacent to the first dam DAM1, and may have a structure in which a bank BANK, a spacer SPACER, a first inorganic encapsulation layer PAS1, and a second inorganic encapsulation layer PAS2 are sequentially stacked.

In addition, the third dam DAM3 may be configured to have a structure in which a spacer, a first inorganic encapsulation layer PAS1, and a second inorganic encapsulation layer PAS2 are sequentially stacked on the upper portion of the bank BANK in the inner direction adjacent to the second dam DAM2.

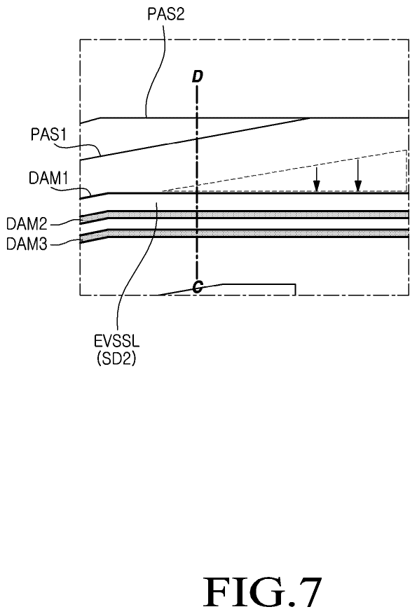

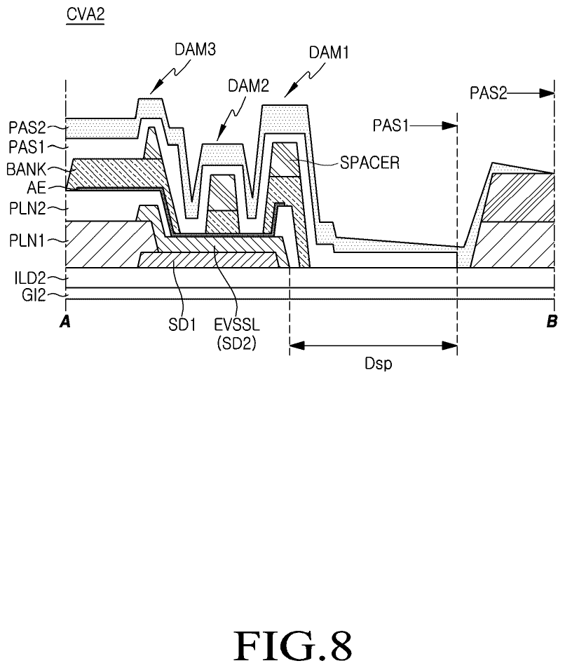

FIG. 7 is an enlarged plan view of a second inorganic layer area in which the ends of the first inorganic encapsulation layer and the second inorganic encapsulation layer gradually approach each other in a display device according to embodiments of the present disclosure, and FIG. 8 illustrates a cross-section taken along the C-D section of the second inorganic layer area in a display device according to embodiments of the present disclosure, as an example.

Referring to FIGS. 7 and 8, in the display device 100 according to embodiments of the present disclosure, the ends of the first inorganic encapsulation layer PAS1 and the ends of the second inorganic encapsulation layer PAS2 may maintain a constant distance in the first inorganic layer area CVA1, but the ends of the first inorganic encapsulation layer PAS1 in the second inorganic layer area CVA2 may gradually come closer to the ends of the second inorganic encapsulation layer PAS2.

The second inorganic layer area CVA2 may correspond to the outer edges on both sides of the pad area PA where the data driving circuit 130 is coupled to the display panel 110.

Depending on the location in the second inorganic layer area CVA2, the end of the first inorganic encapsulation layer PAS1 may be positioned further inside the end of the second inorganic encapsulation layer PAS2, or the end of the first inorganic encapsulation layer PAS1 and the second inorganic encapsulation layer PAS2 may be formed at the same location.

In a portion where the end of the first inorganic encapsulation layer PAS1 is positioned further inside the end of the second inorganic encapsulation layer PAS2, the separation distance Dsp between the end of the pixel low-potential voltage line EVSSL and the end of the first inorganic encapsulation layer PAS1 may be narrowed, similar to the first inorganic layer area CVA1.

As a result, moisture flowing into the link area through the end or seam of the first inorganic encapsulation layer PAS1 may be transferred to the driving voltage lines EVDDL and EVSSL, which may cause the malfunction.

Therefore, by forming the end of the driving voltage lines EVDDL and EVSSL inside the first dam DAM1 in a portion of the second inorganic layer area CVA2 where the end of the first inorganic encapsulation layer PAS1 is located inside the end of the second inorganic encapsulation layer PAS2, the separation distance Dsp between the end of the driving voltage lines EVDDL and EVSSL and the end of the first inorganic encapsulation layer PAS1 can be increased, so that it is possible to effectively block moisture flowing into the link area from the upper portion of the inorganic encapsulation layer PAS1 and PAS2.

In the second inorganic layer area CVA2, one or more dams may be formed to prevent the liquid organic encapsulation layer PCL from collapsing toward the bezel area when formed in the display area DA.

Here, it is exemplified a case where the first dam DAM1, the second dam DAM2, and the third dam DAM3 are formed.

The first dam DAM1 is the outermost dam, and may have a structure in which a second planarization layer PLN2, a bank BANK, a spacer SPACER, a first inorganic encapsulation layer PAS1, and a second inorganic encapsulation layer PAS2 are sequentially stacked.

In this case, the end of the second source-drain electrode pattern SD2 forming the driving voltage line may be located below the second planarization layer PLN2 inside the first dam DAM1. Here, it is illustrated the pixel low-potential voltage line EVSSL transmitting the pixel low-potential voltage EVSS among the driving voltage lines EVDDL and EVSSL as an example.

That is, the pixel low-potential voltage line EVSSL formed of the second source-drain electrode pattern SD2 may be formed so as to extend only to the inside of the first dam DAM1 located at the outermost end of the second inorganic layer area CVA2, and not to extend outside the first dam DAM1.

As a result, the separation distance Dsp between the end of the pixel low-potential voltage line EVSSL and the end of the first inorganic encapsulation layer PAS1 may increases, thereby effectively blocking moisture flowing in from the upper portion of the inorganic encapsulation layer PAS1 and PAS2 from being transmitted to the pixel low-potential voltage line EVSSL in the link area.

In this case, the separation distance Dsp between the end of the pixel low-potential voltage line EVSSL and the end of the first inorganic encapsulation layer PAS1 may be maintained at 60 um or more.

In addition, the end of the pixel low-potential voltage line EVSSL may be arranged to be covered by the second planarization layer PLN2 within the first dam DAM1, thereby effectively blocking moisture from flowing into the link area.

The second dam DAM2 may be positioned inwardly adjacent to the first dam DAM1, and may be configured with a structure in which a bank BANK, a spacer SPACER, a first inorganic encapsulation layer PAS1, and a second inorganic encapsulation layer PAS2 are sequentially stacked.

In addition, the third dam DAM3 may be configured with a structure in which a spacer SPACER, a first inorganic encapsulation layer PAS1, and a second inorganic encapsulation layer PAS2 are sequentially stacked on the upper portion of the bank BANK inwardly adjacent to the second dam DAM2.

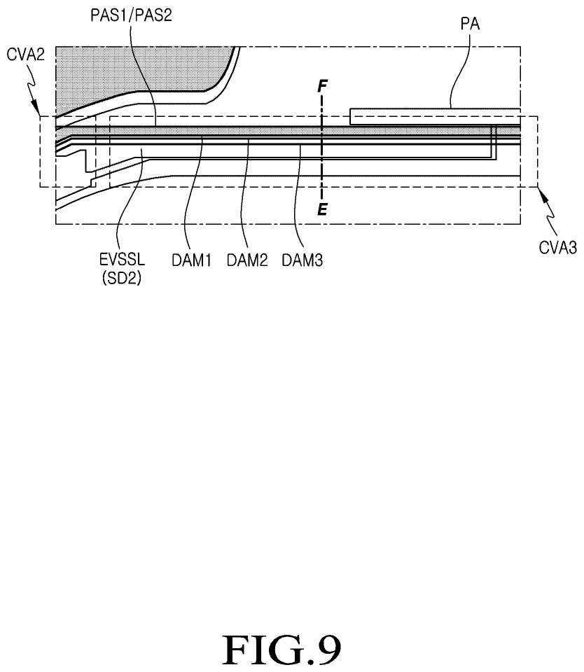

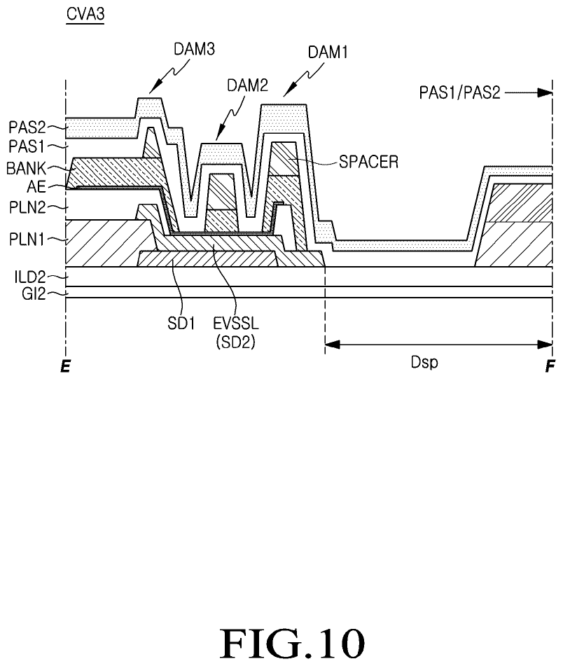

FIG. 9 is an enlarged plan view of a third inorganic layer area in which the end positions of the first inorganic encapsulation layer and the end positions of the second inorganic encapsulation layer are the same in a display device according to embodiments of the present disclosure, and FIG. 10 illustrates an example of a cross-section taken along the E-F section of the third inorganic layer area in a display device according to embodiments of the present disclosure.

Referring to FIGS. 9 and 10, in the display device 100 according to embodiments of the present disclosure, the end positions of the first inorganic encapsulation layer PAS1 and the end positions of the second inorganic encapsulation layer PAS2 in the third inorganic layer area CVA3 may be located on the same line.

The third inorganic layer area CVA3 may correspond to a pad area PA where the data driving circuit 130 is coupled to the display panel 110.

Therefore, since the end of the first inorganic encapsulation layer PAS1 extends to the end of the second inorganic encapsulation layer PAS2 in the third inorganic layer area CVA3, it is possible to secure a sufficient separation distance Dsp between the end of the pixel low-potential voltage line EVSSL and the end of the first inorganic encapsulation layer PAS1.

Therefore, even if the end of the driving voltage line EVDDL and EVSSL protrudes outside the first dam DAM1, if the separation distance Dsp between the end of the driving voltage line EVDDL and EVSSL and the end of the first inorganic encapsulation layer PAS1 is formed to be greater than the distance between the end of the first inorganic encapsulation layer PAS1 and the outermost first dam DAM1, it is possible to block moisture flowing into the link area from the upper part of the inorganic encapsulation layer PAS1 and PAS2.

In addition, the end of the driving voltage lines EVDDL and EVSSL may be formed inside the first dam DAM1 in order to secure the separation distance Dsp between the end of the driving voltage lines EVDDL and EVSSL and the end of the first inorganic encapsulation layer PAS1 greater than the distance between the ends of the first inorganic encapsulation layer PAS1 and the outermost first dam DAM1.

In the third inorganic layer area CVA3, one or more dams may be formed to prevent the liquid-type organic encapsulation layer PCL from collapsing toward the bezel area when formed in the display area DA.

Here, it is illustrated as an example a case where the first dam DAM1, the second dam DAM2, and the third dam DAM3 are formed.

The first dam DAM1 is the outermost dam and may have a structure in which a second planarization layer PLN2, a bank BANK, a spacer SPACER, a first inorganic encapsulation layer PAS1, and a second inorganic encapsulation layer PAS2 are sequentially stacked.

In this case, the end of a second source-drain electrode pattern SD2 forming a driving voltage line may be positioned below the second planarization layer PLN2 inside the first dam DAM1. Here, it is illustrated by example, among the driving voltage lines EVDDL and EVSSL, the pixel low-potential voltage line EVSSL transmitting the pixel low-potential voltage EVSS.

That is, the pixel low-potential voltage line EVSSL formed of the second source-drain electrode pattern SD2 may protrude outside the first dam DAM1 located at the outermost portion of the third inorganic layer area CVA3. Alternatively, the end of the pixel low-potential voltage line EVSSL may be located inside the first dam DAM1.

In this way, a separation distance Dsp between the end of the pixel low-potential voltage line EVSSL and the end of the first inorganic encapsulation layer PAS1 may be determined in consideration of the end position of the first inorganic encapsulation layer PAS1, it is possible to effectively block moisture flowing into the link area from the upper portion of the inorganic encapsulation layer PAS1 and PAS2 from being transferred to the pixel low-potential voltage line EVSSL.

The separation distance Dsp between the end of the pixel low-potential voltage line EVSSL and the end of the first inorganic encapsulation layer PAS1 may be maintained at 60 μm or more.

In addition, if the end of the pixel low-potential voltage line EVSSL is located inside the first dam DAM1, the end of the pixel low-potential voltage line EVSSL may be disposed to be covered by the second planarization layer PLN2, thereby effectively blocking moisture from entering the link area.

The second dam DAM2 may be located inwardly adjacent to the first dam DAM1, and may have a structure in which a bank BANK, a spacer SPACER, a first inorganic encapsulation layer PAS1, and a second inorganic encapsulation layer PAS2 are sequentially stacked.

In addition, the third dam DAM3 may be configured to have a structure in which a spacer, a first inorganic encapsulation layer PAS1, and a second inorganic encapsulation layer PAS2 are sequentially stacked on the upper portion of the bank BANK in the inner direction adjacent to the second dam DAM2.

Meanwhile, the display device 100 of the present disclosure may prevent the distance between the end of the first inorganic encapsulation layer PAS1 and the driving voltage line EVDDL and EVSSL in the link area from becoming closer by moving the location of the point where the end of the first inorganic encapsulation layer PAS1 and the end of the second inorganic encapsulation layer PAS2 meet in the second inorganic layer area CVA2 to the outside of the link area.

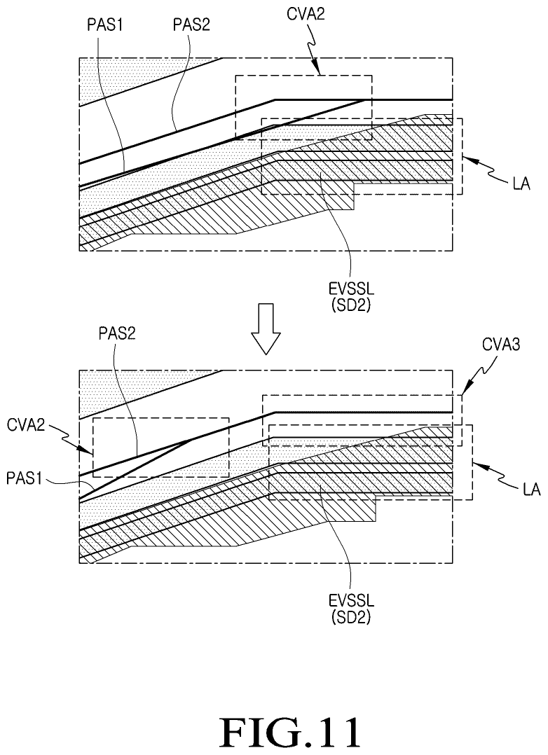

FIG. 11 is a plan view illustrating an example of a display device according to embodiments of the present disclosure, in which the position of the point where the end of the first inorganic encapsulation layer and the end of the second inorganic encapsulation layer meet is moved to the outside of the link area.

Referring to FIG. 11, the second inorganic layer area CVA2, in which the end of the first inorganic encapsulation layer PAS1 gradually approaches the end of the second inorganic encapsulation layer PAS2, may overlap with the link area LA in which the driving voltage lines EVDDL and EVSSL extend through the pad area.

In this way, if the second inorganic layer area CVA2 overlaps with the link area LA, the separation distance Dsp between the end of the first inorganic encapsulation layer PAS1 and the end of the driving voltage lines EVDDL and EVSSL in the second inorganic layer area CVA2 may be narrowed. In this case, moisture flowing into the link area from the upper portion of the inorganic encapsulation layer PAS1 and PAS2 can be transferred to the driving voltage lines EVDDL and EVSSL.

However, if the position of the second inorganic layer area CVA2, in which the end of the first inorganic encapsulation layer PAS1 gradually approaches the end of the second inorganic encapsulation layer PAS2, is moved to the outside of the link area LA, the separation distance Dsp between the end of the first inorganic encapsulation layer PAS1 and the end of the pixel low-potential voltage line EVSSL in the link area LA can be sufficiently increased.

As a result, the separation distance Dsp between the end of the pixel low-potential voltage line EVSSL and the end of the first inorganic encapsulation layer PAS1 in the link area LA may be greater than the distance between the end of the first inorganic encapsulation layer PAS1 and the first dam DAM1, so that moisture flowing into the link area from the upper portion of the inorganic encapsulation layer PAS1 and PAS2 can be effectively blocked from being transferred to the pixel low-potential voltage line EVSSL.

Here, it has been described the case where the pixel low-potential voltage line EVSSL is located outside the pixel high-potential voltage line EVDDL in the link area LA. However, in the case where the pixel high-potential voltage line EVDDL is located outside the pixel low-potential voltage line EVSSL, the effect of moisture inflow can be determined based on the distance between the end of the pixel high-potential voltage line EVDDL and the end of the first inorganic encapsulation layer PAS1.

A display device according to embodiments of the present disclosure may be briefly described as follows.

The display device of the present disclosure may include a display panel including a display area in which a plurality of subpixels are formed and a non-display area divided into a plurality of inorganic layer areas according to the arrangement of a first inorganic encapsulation layer and a second inorganic encapsulation layer outside the display area; a data driving circuit coupled to a pad area of the display panel; and a timing controller for controlling the data driving circuit. In this case, in a link area adjacent to the pad area, a distance between an end of a driving voltage line for transmitting a driving voltage to the plurality of subpixels and an end of the first inorganic encapsulation layer may be formed to be greater than a distance between an end of the first inorganic encapsulation layer and a first dam located at the outermost position.

The plurality of inorganic layer areas may include a first inorganic layer area in which an end of the second inorganic encapsulation layer extending a predetermined distance from an end of the first inorganic encapsulation layer is located, a second inorganic layer area where an end of the first inorganic encapsulation layer gradually approaches an end of the second inorganic encapsulation layer, and a third inorganic layer area where an end of the first inorganic encapsulation layer coincides with an end of the second inorganic encapsulation layer.

The third inorganic layer area may be located in the pad area, the second inorganic layer area may be located on both outer sides of the third inorganic layer area, and the first inorganic layer area may be located in an area other than the second inorganic layer area and the third inorganic layer area.

In the first inorganic layer area, the first dam may be formed between the display area and the end of the first inorganic encapsulation layer, and the end of the driving voltage line may be formed within the first dam.

The first dam may have a structure in which a planarization layer, a bank, a spacer, the first inorganic encapsulation layer, and the second inorganic encapsulation layer are sequentially stacked. The end of the driving voltage line may be located below the planarization layer.

The first inorganic layer area may further include a second dam and a third dam formed between the display area and the first dam. The second dam may be located inwardly adjacent to the first dam and has a structure in which a bank, a spacer, the first inorganic encapsulation layer, and the second inorganic encapsulation layer are sequentially stacked. The third dam may be configured with a structure in which a spacer, the first inorganic encapsulation layer, and the second inorganic encapsulation layer are sequentially stacked on an upper portion of an inward bank adjacent to the second dam. The driving voltage line may be located below the second dam and the third dam.

In the second inorganic layer area, at least one dam may be formed between the display area and the end of the first inorganic encapsulation layer, and the end of the driving voltage line may be formed inside the dam.

In the third inorganic layer area, at least one dam may be formed between the display area and the end of the first inorganic encapsulation layer, and the dam may have a structure in which a planarization layer, a bank, a spacer, the first inorganic encapsulation layer, and the second inorganic encapsulation layer are sequentially stacked. The end of the driving voltage line may extend to the outside of the planarization layer.

The driving voltage line may include a pixel low-potential voltage line for transmitting a pixel low-potential voltage to the plurality of subpixels, and a pixel high-potential voltage line for transmitting a pixel high-potential voltage to the plurality of subpixels. The pixel low-potential voltage line may be located outside the pixel high-potential voltage line.

The plurality of subpixels may include a substrate, a first transistor formed of a low temperature polysilicon transistor on the substrate, a second transistor formed of an oxide transistor on the substrate, a driving transistor formed of an oxide transistor on the substrate, a first source-drain electrode pattern forming a source electrode and a drain electrode of the first transistor, the second transistor, and the driving transistor, a first planarization layer formed to cover the first source-drain electrode pattern, a second source-drain electrode pattern electrically connected to the first source-drain electrode pattern through a contact hole in the first planarization layer, a second planarization layer formed to cover the second source-drain electrode pattern, a light emitting device formed on the second planarization layer, and an encapsulation layer formed by sequentially stacking the first inorganic encapsulation layer, an organic encapsulation layer, and the second inorganic encapsulation layer on the light emitting device.

The driving voltage line may be formed by the second source-drain electrode pattern.

The second inorganic layer area may be formed on the outside of the link area.

A display panel according to embodiments of the present disclosure may include a display area in which a plurality of subpixels are formed, a non-display area in which a plurality of inorganic layer areas are divided according to an arrangement of a first inorganic encapsulation layer and a second inorganic encapsulation layer outside the display area, and in which a plurality of dams are positioned, a pad area in which a data driving circuit is coupled, and a link area in which a driving voltage line transmitting a driving voltage to the plurality of subpixels extends through the pad area. A distance between the end of the driving voltage line and the end of the first inorganic sealing layer may be greater than a distance between the end of the first inorganic encapsulation layer and the outermost first dam.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel including a display area having a plurality of subpixels, and a non-display area divided into a plurality of inorganic layer areas according to an arrangement of a first inorganic encapsulation layer and a second inorganic encapsulation layer outside the display area and including a plurality of dams;
a data driving circuit coupled to a pad area of the display panel; and
a timing controller configured to control the data driving circuit,
wherein, in a link area adjacent to the pad area, an end of a driving voltage line configured to transmit a driving voltage to the plurality of subpixels is located inside a first dam at an outermost position among the plurality of dams.

2. The display device of claim 1, wherein the plurality of inorganic layer areas include:
a first inorganic layer area in which an end of the second inorganic encapsulation layer extending a predetermined distance from an end of the first inorganic encapsulation layer is located;
a second inorganic layer area where an end of the first inorganic encapsulation layer gradually approaches an end of the second inorganic encapsulation layer; and
a third inorganic layer area where an end of the first inorganic encapsulation layer coincides with an end of the second inorganic encapsulation layer.

3. The display device of claim 2, wherein the third inorganic layer area is located in the pad area,
wherein the second inorganic layer area is located on two outer sides of the third inorganic layer area,
wherein the first inorganic layer area is located in an area different from the second inorganic layer area and the third inorganic layer area.

4. The display device of claim 2, wherein, in the first inorganic layer area, the first dam is between the display area and the end of the first inorganic encapsulation layer, and the end of the driving voltage line is within the first dam.

5. The display device of claim 4, wherein the first dam has a structure in which a planarization layer, a bank, a spacer, the first inorganic encapsulation layer, and the second inorganic encapsulation layer are sequentially stacked,
wherein the end of the driving voltage line is located below the planarization layer.

6. The display device of claim 4, wherein the first inorganic layer area further includes a second dam and a third dam between the display area and the first dam,
wherein the second dam is inwardly adjacent to the first dam and has a structure in which a bank, a spacer, the first inorganic encapsulation layer, and the second inorganic encapsulation layer are sequentially stacked,
wherein the third dam has a structure in which a spacer, the first inorganic encapsulation layer, and the second inorganic encapsulation layer are sequentially stacked on an upper portion of an inward bank adjacent to the second dam;
wherein the driving voltage line is located below the second dam and the third dam.

7. The display device of claim 2, wherein, in the second inorganic layer area, the first dam is formed between the display area and the end of the first inorganic encapsulation layer, and the end of the driving voltage line is formed inside the first dam.

8. The display device of claim 7, wherein the first dam has a structure in which a planarization layer, a bank, a spacer, the first inorganic encapsulation layer, and the second inorganic encapsulation layer are sequentially stacked,
wherein the end of the driving voltage line is located below the planarization layer.

9. The display device of claim 8, wherein the second inorganic layer area further includes a second dam and a third dam between the display area and the first dam,
wherein the second dam is inwardly adjacent to the first dam and has a structure in which a bank, a spacer, the first inorganic encapsulation layer, and the second inorganic encapsulation layer are sequentially stacked,
wherein the third dam is inwardly adjacent to the second dam and has a structure in which a spacer, the first inorganic encapsulation layer, and the second inorganic encapsulation layer are sequentially stacked,
wherein the driving voltage line is located below the second dam and the third dam.

10. The display device of claim 2, wherein, in the third inorganic layer area, the first dam is between the display area and the end of the first inorganic encapsulation layer,
wherein the first dam has a structure in which a planarization layer, a bank, a spacer, the first inorganic encapsulation layer, and the second inorganic encapsulation layer are sequentially stacked,
wherein the end of the driving voltage line extends to the outside of the planarization layer.

11. The display device of claim 1, wherein the driving voltage line includes:
a pixel low-potential voltage line for transmitting a pixel low-potential voltage to the plurality of subpixels; and
a pixel high-potential voltage line for transmitting a pixel high-potential voltage to the plurality of subpixels,
wherein the pixel low-potential voltage line is located outside the pixel high-potential voltage line.

12. The display device of claim 1, wherein the plurality of subpixels include:
a substrate;
a first transistor formed of a low temperature polysilicon transistor on the substrate;
a second transistor formed of an oxide transistor on the substrate;
a driving transistor formed of an oxide transistor on the substrate;
a first source-drain electrode pattern including a source electrode and a drain electrode of the first transistor, the second transistor, and the driving transistor;
a first planarization layer that covers the first source-drain electrode pattern;
a second source-drain electrode pattern electrically connected to the first source-drain electrode pattern through a contact hole in the first planarization layer;
a second planarization layer that covers the second source-drain electrode pattern;
a light emitting device on the second planarization layer; and
an encapsulation layer including the first inorganic encapsulation layer, an organic encapsulation layer, and the second inorganic encapsulation layer sequentially stacked on the light emitting device.

13. The display device of claim 12, wherein the driving voltage line is part of the second source-drain electrode pattern.

14. The display device of claim 2, wherein the second inorganic layer area is on the outside of the link area.

15. The display device of claim 1, wherein a separation distance between the end of the drive voltage line and the end of the first inorganic encapsulation layer is at 60 μm or more.

16. A display panel comprising:
a display area having a plurality of subpixels;
a non-display area in which a plurality of inorganic layer areas are divided according to an arrangement of a first inorganic encapsulation layer and a second inorganic encapsulation layer outside the display area, and in which a plurality of dams are positioned;
a pad area coupled to a data driving circuit; and
a link area in which a driving voltage line for transmitting a driving voltage to the plurality of subpixels extends through to the pad area,
wherein an end of the driving voltage line is inside a first dam at an outermost position among the plurality of dams.
